(19) United States
(12) Patent Application Publication
(10) Pub. No.: US 2009/0128136 A1
(43) Pub. Date: May 21, 2009

(54) Device and process for non-contacting determination of a state variable, in particular the position, of at least one pipeline pig

(75) Inventor: Andreas Hablizel, Reutlingen (DE)

Correspondence Address: FACTOR & LAKE, LTD, 1327 W. WASHINGTON BLVD., SUITE 5G/H, CHICAGO, IL, 60607, US

(73) Assignee: EISENMANN ANLAGENBAU GMBH & CO. KG, Boeblingen (DE)

(21) Appl. No.: 12/270,583

(22) Filed: Nov. 13, 2008

(30) Foreign Application Priority Data
Nov. 17, 2007 (DE) 10 2007 054 969.7

(51) Int. Cl. H01L 43/06

(52) U.S. Cl. 324/207.2

(57) ABSTRACT

A device and a process are described for non-contacting determination of a state variable, in particular the position, of at least one pipeline pig which is displaceable in a supply path. The pipeline pig includes a magnetic-field source. The device exhibits at least one sensor responding to the presence of the magnetic-field source. Said device is, in addition, provided with a circuit arrangement, to which the sensor-output signal of the sensor can be supplied and which generates an electrical output signal that is representative of the state variable of the pipeline pig at the sensor. A plurality of preferably identical sensors connected in parallel are arranged in succession along the supply path in the direction of motion of the pipeline pig.

### RELATED APPLICATIONS

This application claims the filing benefit of German Patent Application No. 10 2007 054 969.7 filed Nov. 17, 2007, the contents of all of which are incorporated herein by reference.

### BACKGROUND OF THE INVENTION

The invention relates to a device for non-contacting determination of a state variable, in particular the position, of at least one pipeline pig which is displaceable in a supply path and which includes a magnetic-field source, with at least one sensor responding to the presence of the magnetic-field source; and a circuit arrangement to which a sensor-output signal of the sensor can be supplied and which generates an electrical output signal that is representative of the state variable of the pipeline pig at the sensor.

In addition, the invention relates to a process for non-contacting determination of a state variable, in particular the position, of at least one pipeline pig which is displaced in a supply path and by which a magnetic-field source is carried, wherein the presence of the magnetic-field source is registered with at least one sensor; and a sensor-output signal of the sensor is supplied to a circuit arrangement and with the latter an electrical output signal is generated that is representative of these state variables of the pipeline pig at the sensor.

In the field of coating technology it is common to convey coating material through a tube—for example, from a supply source to another place, in particular to an application device—with the aid of a pipeline pig. The pipeline pig can also be moved on its own, for example for the purpose of cleaning the tube. The motion of the pipeline pig, in particular the presence thereof at the various pipeline-pig stations, is monitored with the aid of devices of the type mentioned in the introduction.

Known from DE 102 20 676 B4 are a device of such a type and a process of such a type, wherein a magnet is integrated within a pipeline pig. In the case where the pipeline pig is present in a pipeline-pig station, the magnet is detected with the aid of a sensor, within which a magnetic-field-sensitive switch is integrated. A circuit arrangement generates from a sensor signal an electrical output signal that is representative of the presence or absence of the pipeline pig at the sensor.

Frequently, however, it is necessary to obtain, besides the presence or absence of the pipeline pig at particular places, yet further state variables of the pipeline pig, preferably the speed thereof, its precise position in the pipeline-pig tube also between the pipeline-pig stations, and/or the distance covered by it. Furthermore, state variables characterising a transportation state of coating material to be conveyed, preferably the volume and/or the volumetric flow rate of the coating material being transported, are also often needed.

The present invention is directed to resolving these and other matters.

### SUMMARY OF THE INVENTION

An object of the present invention is to configure a device and a process of the type mentioned in the introduction in such a way that by simple means as much information as possible is obtained about the state variables of the pipeline pig and, as far as possible, also about the transport state of the coating material. Furthermore, the device is to operate, as far as possible, in wear-free manner.

In accordance with the invention, this object may be achieved by a plurality of preferably identical sensors connected in parallel being arranged in succession along the supply path in the direction of motion of the pipeline pig.

In accordance with the invention, the magnetic field of the pipeline pig can accordingly generate a sensor signal in each sensor when passing through the pipeline-pig tube. In this way, the pipeline pig can be tracked along the supply path, as far as possible in gap-free manner. This enables an optimal determination of the location and the speed of the pipeline pig.

In an advantageous embodiment, the sensors each include at least one conductor winding which is arranged around the supply path in the manner of a coil, the ends of which are connected to corresponding signal inputs of the circuit arrangement, whereby between the ends of the conductor winding an a.c. voltage sensor-output signal is applied which characterises the motion of the pipeline pig in the region of the conductor winding and which is induced by the magnetic-field source. Accordingly, a plurality of conductor windings in the form of individual coils can be wound around the supply path, preferably a pipeline-pig tube or a pipe, or can be pushed over the supply path in the form of separate structural elements on a respective coil core. The conductor windings act as stators of linearly arranged generators. In this case the magnetically acting pipeline pig has the function of the rotor. In the course of the motion of the pipeline pig along the supply path, an a.c. voltage pulse is induced overall by the magnetic field on passing through the conductor winding. The polarity of the a.c. voltage pulse on moving out of the conductor winding is contrary to the polarity on moving in. From this a.c. voltage pulse the presence of the pipeline pig at or in the conductor winding can be registered easily, and in this way the position of the pipeline pig can be ascertained. The conductor winding can furthermore be easily connected to the circuit arrangement with a shielded two-wire line. The registration of the state variables of the pipeline pig is furthermore totally wear-free, since the conductor winding—as distinct from the magnetic-field-sensitive switch known from the state of the art—contains no moving parts. In addition, conductor windings require no power supply in order to be operated.

In a further advantageous embodiment, the sensors each include a Hall element, in particular a Hall switch. Hall elements are small, compact and robust structural elements. Hall switches have the advantage that they already provide a digital output signal as soon as the magnetic-field source is located in their vicinity. The digital output signal only has to be adapted with respect to its level for the following circuit arrangement. By reason of their small dimension, a plurality of Hall elements can be densely accommodated in a relatively small space, and in this way the local resolution of the detection of the position of the pipeline pig can be improved.

In order to improve the local resolution in connection with the registration of the pipeline pig, the sensors can, in particular, be arranged around the supply path in uniformly distributed manner, preferably in the form of a helix.

In a manner that is particularly simple, not susceptible to interference, and inexpensive, the magnetic-field source of the pipeline pig may be a permanent magnet or a ferrite core.

In advantageous manner the circuit arrangement may exhibit means for determining electrical output signals from the sensor-output signal that are representative of at least one of the following state variables of the pipeline pig and/or of a coating material to be conveyed: the position of the pipeline pig on the supply path, the distance covered by the pipeline pig on the supply path, the speed of the pipeline pig, the volume of coating material conveyed with the pipeline pig, and the volumetric flow rate of the coating material conveyed with the pipeline pig.

In order to be able to process the a.c. voltage sensor-output signals of the conductor windings easily with a logic circuit, the circuit arrangement may exhibit means for transforming the a.c. voltage sensor-output signal into a square-wave signal.

In expedient manner the circuit arrangement may exhibit means for inverting the negative or the positive component of the a.c. voltage sensor-output signal or of an a.c. voltage signal derived therefrom. In this way, the two components can be rectified, and the levels thereof can be easily adapted for further processing in a subsequent logic circuit.

In order easily to ascertain the number of sensors passed through, the circuit arrangement may exhibit means for counting sensor-output signals or signal pulses derived therefrom. From the number of sensor-output signals, the distance covered and, from this, the position of the pipeline pig can be easily determined.

Furthermore, the circuit arrangement may exhibit a timing element with which a time window can be predetermined, and by counting of the sensor-output pulses within the time window the speed can be ascertained. In this way, the speed of the pipeline pig and, from this, a volumetric flow rate of the coating agent can be calculated with the circuit arrangement from the distance covered by the pipeline pig.

In advantageous manner the circuit arrangement may exhibit means for registering the sequence of negative and positive components of the a.c. voltage sensor-output signal. In this way, interference pulses can be detected and ignored if the sequence of negative and positive components does not alternate. This may be the case, for example, when interference pulses are present.

The process according to the invention is characterised in that the presence of the magnetic-field source is registered with a plurality of sensors which are arranged in succession along the supply path in the direction of motion of the pipeline pig and are connected in parallel.

In this way, in simple and wear-free manner the motion and the position of the pipeline pig in the pipeline-pig tube are registered in almost gap-free manner.

In an advantageous configuration of the process, with the magnetic-field source in respective conductor windings of the sensors, which are arranged in the manner of a coil around the supply path, an a.c. voltage sensor-output signal characterising the motion of the pipeline pig in the region of the conductor winding is induced. A.c. voltage signals can be registered easily and examined for any possible interference pulses.

In another advantageous configuration of the process, a Hall voltage characterising the motion of the magnetic-field source, or a digital output signal, is generated with respective Hall elements, in particular Hall switches. Hall elements are very compact, so the they can be installed in great density along the supply path in order to obtain a high local resolution. With Hall switches, digital signals are already output that can be easily subjected to further processing with the circuit arrangement.

In advantageous manner, from the sensor-output signals electrical output signals are ascertained that are representative of at least one of the following state variables of the pipeline pig and/or of a coating material to be conveyed: the position of the pipeline pig on the supply path, the distance covered by the pipeline pig on the supply path, the speed of the pipeline pig, the volume of coating material conveyed with the pipeline pig, and the volumetric flow rate of the coating material conveyed with the pipeline pig.

In this way a large number of items of information about the pipeline-pig system, in particular the functionality thereof and its functional states, can be ascertained by simple means with little sensory effort. In this way, the wear of pipeline pigs during operation can also be detected.

It is to be understood that the aspects and objects of the present invention described above may be combinable and that other advantages and aspects of the present invention will become apparent upon reading the following description of the drawings and detailed description of the invention.

### BRIEF DESCRIPTION OF THE DRAWINGS

FIG. 1 a first device for detecting a pipeline pig contained a magnetised ferrite core, wherein a pipeline-pig tube is wrapped with a plurality of individual coils;

FIG. 2 a voltage/time diagram in which sinusoidal a.c. voltage output pulses are represented which are generated with a circuit arrangement from a.c. voltage output—signals induced in the individual coils when the pipeline pig passes;

FIG. 3 a further voltage/time diagram in which square-wave signals are represented which are ascertained from the sinusoidal a.c. voltage output pulses of FIG. 2;

FIG. 4 a position/time diagram with a stepwise representation of the motion of the pipeline pig in the pipeline-pig tube of FIG. 1;

FIG. 5 a second pipeline-pig-detecting device which is similar to that shown in FIGS. 1 to 4, wherein a plurality of Hall switches are arranged in a single straight line along the pipeline-pig tube;

FIG. 6 a longitudinal section of a pipeline-pig tube with a third pipeline-pig-detecting device which is similar to that shown in FIG. 5, wherein a plurality of Hall switches are arranged along the pipeline-pig tube, distributed onto four straight lines in the form of a helix overall;

FIG. 7 a cross-section of the pipeline-pig-detecting device from FIG. 6;

FIG. 8 a longitudinal section of a pipeline-pig tube with a fourth pipeline-pig-detecting device which is similar to that from FIGS. 6 and 7, wherein the Hall switches are distributed onto three straight lines;

FIG. 9 a cross-section of the pipeline-pig-detecting device from FIG. 8;

FIG. 10 a longitudinal section of a pipeline-pig tube with a fifth pipeline-pig-detecting device which is similar to that from FIGS. 6 to 9, wherein the Hall switches are distributed onto two straight lines;

FIG. 11 a cross-section of the pipeline-pig-detecting device from FIG. 10.

### DETAILED DESCRIPTION OF THE PRESENT INVENTION

While this invention is susceptible of embodiment in many different forms, there is shown in the drawings and will herein be described in detail one or more embodiments with the understanding that the present disclosure is to be considered as an exemplification of the principles of the invention and is not intended to limit the invention to the embodiments illustrated.

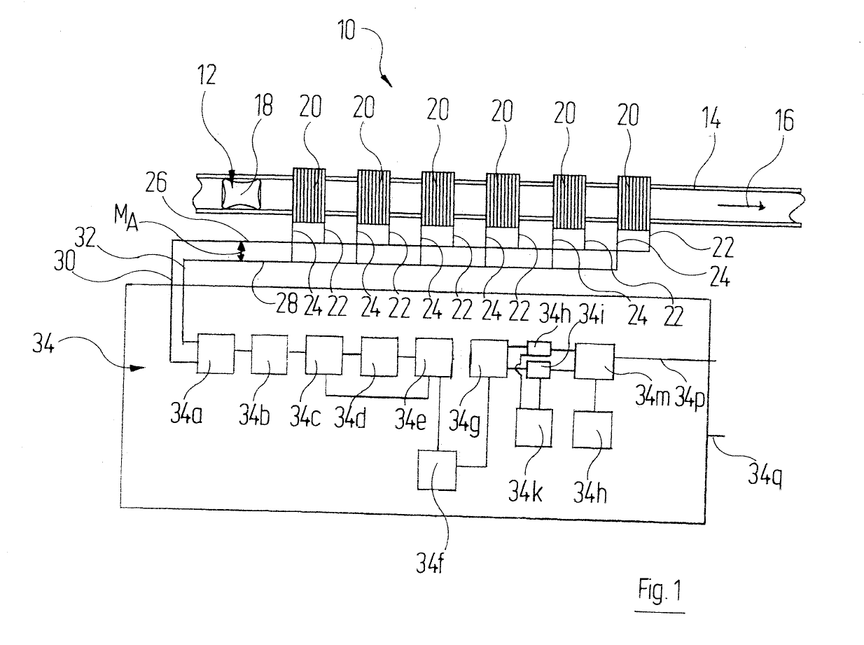

In FIG. 1 a device for detecting a pipeline pig 12 in a pipeline-pig tube 14 is shown, provided overall with reference symbol 10.

The pipeline-pig tube 14 forms a supply path for lacquer which is conveyed from a supply source, which is not shown in FIG. 1, to an application device which is of no further interest here, for example a spray gun.

The pipeline pig 12 is capable of being moved in the pipeline-pig tube 14 and in this way pushes the lacquer ahead of it in known manner in the direction of motion (arrow 16).

The pipeline pig 12 is preferably a rubbery, circular cylindrical stopper. The external profile of the pipeline pig 12 perpendicular to the direction of motion 16 corresponds to the internal profile of the pipeline-pig tube 14, so the pipeline pig 12 is able to slide along the inner wall of the pipeline-pig tube 14 as tightly as possible and nevertheless with slight friction losses. In its interior the pipeline pig 12 exhibits a magnetic core 18, for example a ferrite core.

Around the pipeline-pig tube 14 a plurality of identical individual coils 20 having the same direction of winding are wound cylindrically in succession at equal intervals in the direction of motion 16. The individual coils 20 each exhibit an insulated, electrically conductive coil wire which is wound around the pipeline-pig tube 14 in one or more layers.

The individual coils 20 are connected in parallel, with like polarity. The posterior ends 22, in the direction of motion 16, of the coil wires are connected for this purpose to a first signal line 26 which leads to a first input 30 of a circuit arrangement 34. The anterior ends 24, in the direction of motion 16, of the coil wires are connected to a second signal line 28 which leads to a second input 32 of the circuit arrangement 34. The signal lines 26 and 28 are realised as a shielded two-wire line.

When the pipeline pig 12 passes through the region of an individual coil 20, an a.c. voltage sensor-output signal UA is induced in the individual coil 20 by the magnetic field of the ferrite core 18.

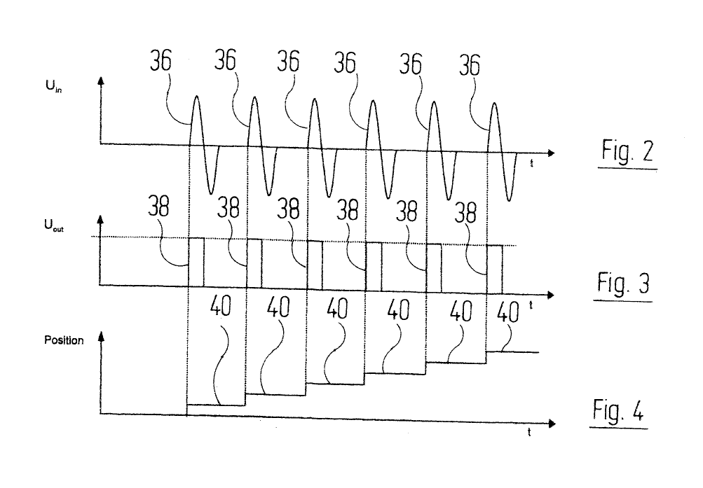

The a.c. voltage sensor-output signal UA is supplied to the circuit arrangement 34 via the signal lines 26 and 28. The circuit arrangement 34 exhibits a filter 34a, with which the a.c. voltage sensor-output signal UA is firstly filtered. Then the filtered, now sinusoidal signal is amplified with an appropriate amplifier 34b for the purpose of further signal processing into sinusoidal a.c. voltage output pulses 36 (FIG. 2).

The a.c. voltage output pulses 36 which arise when the pipeline pig 12 moves through the individual coils 20 in the direction of motion 16 are shown in FIG. 2 in a voltage(Uin)/time(t) diagram. When the pipeline pig 12 is moving uniformly at constant speed, the a.c. voltage output pulses 36 are identical, since the individual coils 20 are also identical.

The polarity of the a.c. voltage output pulses 36 when the pipeline pig 12 moves into one of the individual coils 20 is contrary to the polarity when moving out of the region of the individual coil 20. When the pipeline pig 12 enters the region of the individual coils 20, in the case of the structure shown in FIG. 1 firstly a positive half-wave—at the top in FIG. 2—is generated. Upon exiting the region of the individual coils 20, a negative half-wave—at the bottom in FIG. 2—is generated. In the regions between the individual coils 20 the voltage Uin falls to virtually zero.

The circuit arrangement 34 furthermore exhibits a comparator circuit 34c, with which the positive half-waves of the a.c. voltage output pulses 36 can be separated from the negative half-waves. Both in the case of the positive half-wave and in the case of the negative half-wave, in this process the signal noise is also filtered out, since the signal levels thereof lie below the reference level of the comparator.

The negative half-waves are inverted with an inverter 34d of the circuit arrangement 34.

Both half-waves are converted into square-wave signals with a pulse-shaper 34e. The square-wave signals 38 which are generated from the positive half-waves of the a.c. voltage output pulses 36 are shown in FIG. 3 in a further voltage(Uout)/time(t) diagram.

The square-wave signals 38 from the positive half-waves and the square-wave signals, not shown, from the negative half-waves are subjected to further processing with a downstream logic circuit 34f of the circuit arrangement 34. With the logic circuit 34f it is examined whether a negative half-wave follows each positive half-wave. An alternating polarity of such a type is obligatory in the case of an error-free registration of the a.c. voltage sensor-output signals UA when the pipeline pig 12 passes. If an error in the sequence is detected, the a.c. voltage sensor-output signal UA, the polarity of which does not fit into the sequence, is not taken into any further account by the logic circuit 34f.

The square-wave signals 38 from the positive half-waves of the a.c. voltage output pulses 36 are brought, by an amplifier 34g in the circuit arrangement 34, to a level at which they can be counted with a subsequent counter circuit 34h of the circuit arrangement 34.

The negative half-waves of the a.c. voltage output pulses 36 are also transformed into positive square-wave pulses and are counted with a further counter circuits 34i. In the course of the following plausibility check of the a.c. voltage output pulses 36 a check is made with the two counter circuits 34h and 34i as to whether the total number of square-wave signals—that is to say, the square-wave signals from the positive half-waves and from the negative half-waves—is an even-numbered multiple of the number of individual coils 20 passed through. If this is not the case, an error in the counting, or an interfering pulse, is present.

Furthermore, a time window is predetermined with a timing element 34k of the circuit arrangement 34. With the circuit arrangement 34 the speed of the pipeline pig 12 is determined by the number of square-wave signals 38 being ascertained that have resulted from the positive half-waves within the time window.

From the number of square-wave signals 38, the position of the pipeline pig 12 in the pipeline-pig tube 14 is ascertained. For this purpose, with the circuit arrangement 34 with each square-wave signal 38 a predetermined value is added to a defined initial-position value. The predetermined value corresponds to the spacing between the anterior input sides, in the direction of motion 16, of two adjacent individual coils 20. This is because this is the distance that the pipeline pig 12 covers between two square-wave signals 38.

In FIG. 4 a stepped position/time diagram is shown for the position of the pipeline pig 12, said diagram resulting from the progression of the square-wave signals 38 from FIG. 3. In this case each step 40 corresponds to the position of an individual coil 20 on the pipeline-pig tube 14 relative to the first individual coil 20 in the direction of motion 16.

In order to determine the distance covered by the pipeline pig 12 between two individual coils 20, the number of pulses is counted that are ascertained during the motion of the pipeline pig 12 within the time window.

By multiplication of the distance covered by the pipeline pig 12 by the known cross-section of the pipeline-pig tube 14, furthermore the volume of conveyed lacquer is determined.

By multiplication of the volume per unit length of the conveyed lacquer by the speed of the pipeline pig 12, the volumetric flow rate of the lacquer is calculated with the circuit arrangement 34.

In this way, separate measuring cells with which the amount of lacquer is metered are not required.

The ascertained state variables—constituted by position of the pipeline pig 12, distance covered, volume of conveyed lacquer, and volumetric flow rate of the lacquer—are communicated, for example, to a display, which is not shown, or to a control unit, which is of no further interest here, of the pipeline-pig system via an interface 34q of the circuit arrangement 34.

The circuit arrangement 34 furthermore exhibits a wear-testing circuit 34m for the pipeline pig 12 and the pipeline-pig tube 14. With the wear-testing circuit 34m the actual speed of the pipeline pig is compared with a set speed of the pipeline pig, which is stored in a memory unit 34n in the form of a master curve for the corresponding boundary conditions, for example the type of lacquer. If the actual speed of the pipeline pig lies outside a predetermined tolerance range around the set speed of the pipeline pig, a warning signal is output at an interface 34p of the circuit arrangement 34. The warning signal can likewise be communicated to the display or to the control unit of the pipeline-pig system.

Such a deviation of the actual speed of the pipeline pig from the set speed of the pipeline pig may be caused, for example, by wear of the pipeline pig 12 and/or of the pipeline-pig tube 14. But the reason may also be a leak in the pipeline-pig tube 14, from which lacquer is escaping. As a result of the loss of lacquer, the mechanical resistance that is acting on the pipeline pig 12 decreases, so the latter travels more quickly. In this way, a check of the tightness of the pipeline-pig system is also easily realised.

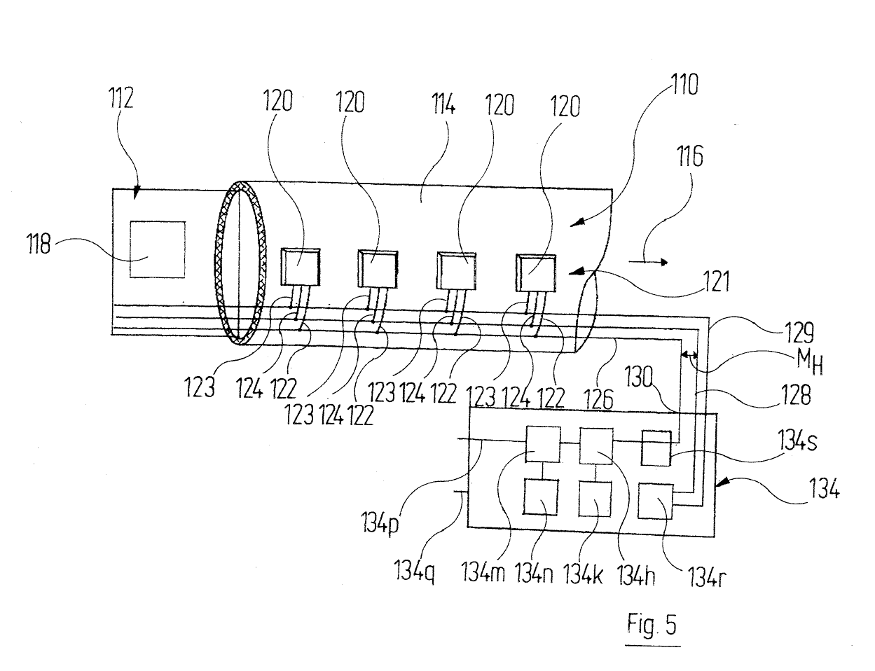

In a second exemplary embodiment, represented in FIG. 5, those elements which are similar to those of the first exemplary embodiment, described in FIGS. 1 to 4, are provided with the same reference symbols plus 100, so that with respect to the description thereof reference is made to the remarks relating to the first exemplary embodiment. This exemplary embodiment differs from first in that, instead of the individual coils 20, a plurality of Hall switches 120, known as such, are used as sensors. The Hall switches 120 are arranged in succession on the pipeline-pig tube 114 in equidistant manner in the direction of motion 116 in the form of a single straight line 121.

The Hall switches 120 are fastened externally to the peripheral side of the pipeline-pig tube 114.

The line 121 extends parallel to the axis of the pipeline-pig tube 112.

In the case of the Hall switches 120, it is a question of unipolar or bipolar Hall-sensor switches.

Each Hall switch 120 is provided with a signal terminal 122, an earth terminal 124 and a supply-voltage terminal 123.

Via the supply-voltage terminals 123 the Hall switches 120 are fed with a supply voltage. The supply voltage is made available from a voltage source 134r of a circuit arrangement 134 via a central supply-voltage line 129.

The earth terminals 124 are likewise connected to the voltage source 134r via a central earth line 128.

At the signal terminal 122 a digital output signal in the form of a voltage pulse UH is earthed as soon as the pipeline pig 112 with the ferrite core 118 comes into the region of the respective Hall switch 120.

The Hall switches 120 are functionally connected in parallel. All the signal terminals 122 are connected to a signal input 130 of the circuit arrangement 134 via a central signal line 126.

The digital output signals UH are supplied from the signal input 130 to a level circuit 134s, with which the level is adapted for the subsequent counter circuit 134h.

The level circuit 134s exhibits a dropping resistor and a Zener diode.

A square-wave signal in the manner of the square-wave signal shown in FIG. 3 (first exemplary embodiment) is applied overall at the output of the level circuit 134s when the pipeline pig 120 passes.

In a manner analogous to the first exemplary embodiment (FIGS. 1 to 4), the square-wave signal is processed—with the aid of a timing element 134k, a wear-testing circuit 134m and a memory unit 134n—into the signals that are representative of the state variables of the pipeline pig 112 or of the lacquer which were elucidated in more detail in connection with the first exemplary embodiment, and is output at interfaces 134p and 134q.

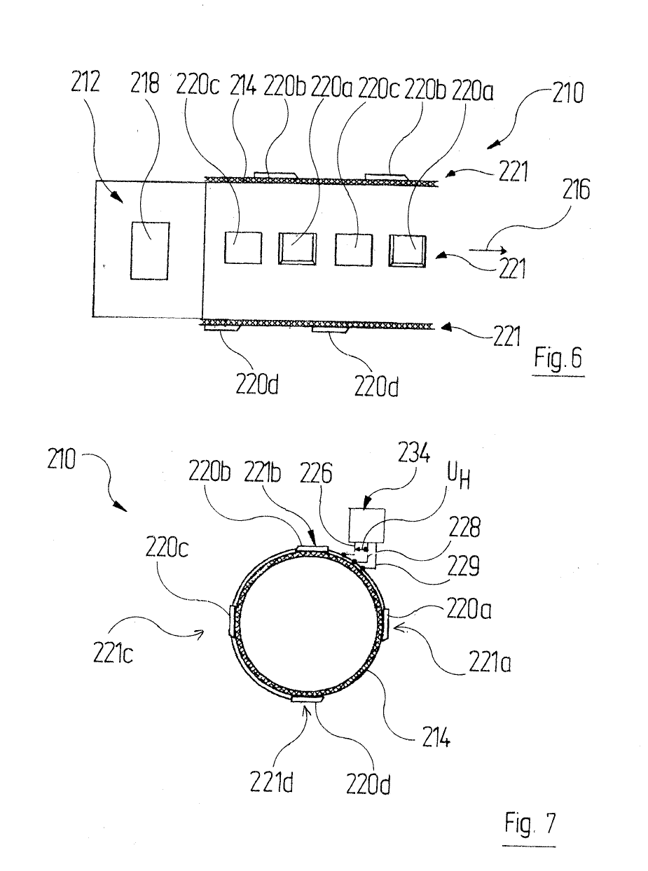

In a third exemplary embodiment, represented in FIGS. 6 (longitudinal section) and 7 (cross-section), those elements which are similar to those of the second exemplary embodiment, described in FIG. 5, are provided with the same reference symbols plus 100, so that with respect to the description thereof reference is made to the remarks relating to the second exemplary embodiment. This exemplary embodiment differs from second in that, instead of only one line 121 of Hall switches 120, in the case of the second exemplary embodiment four lines 221a, 221b, 221c, 221d of Hall switches 220a, 220b, 220c, 220d are provided. The lines 221a, 221b, 221c, 221d run parallel to the axis of the pipeline-pig tube 214 and are uniformly distributed in the peripheral direction of the pipeline-pig tube 214, considered in cross-section (FIG. 7), at the corners of a square.

The Hall switches 220a, 220b, 220c, 220d of the four lines 221a, 221b, 221c, 221d are in this case offset relative to one another, so that the Hall switches 220a, 220b, 220c, 220d are placed overall along an imaginary helix around the pipeline-pig tube 214. The spacings of consecutive Hall switches 220 on the imaginary helix of adjacent lines 221 are dimensioned in such a way that when the pipeline pig 212 moves a gap-free tracking of the same is possible with higher local resolution than with only one line, whereby the output signals UH from the Hall switches 220 are just still capable of being registered separately. All the Hall switches 220a, 220b, 220c, 220d are functionally connected in parallel in a manner analogous to the second exemplary embodiment.

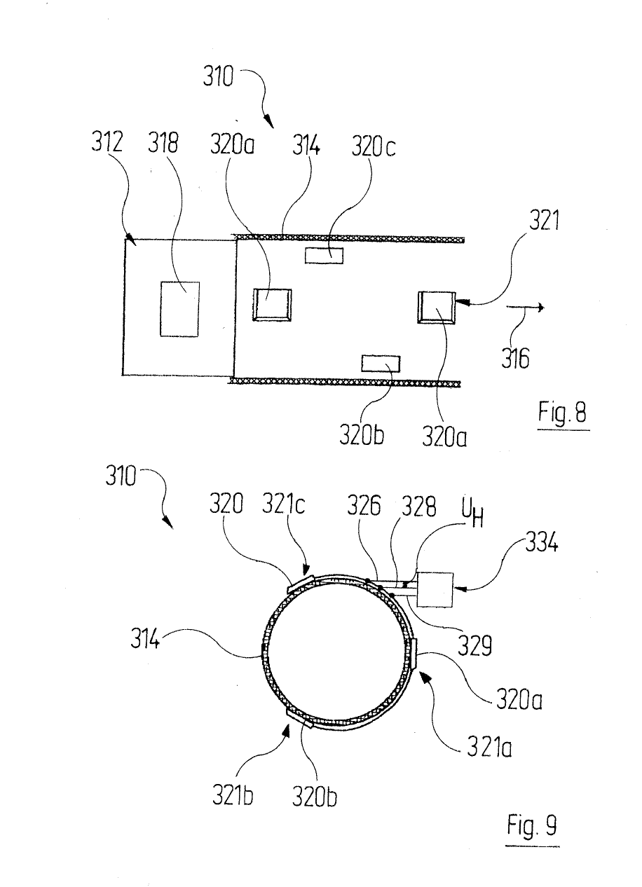

In a fourth exemplary embodiment, represented in FIGS. 8 (longitudinal section) and 9 (cross-section), those elements which are similar to those of the third exemplary embodiment, described in FIGS. 6 and 7, are provided with the same reference symbols plus 100, so that with respect to the description thereof reference is made to the remarks relating to the third exemplary embodiment. This exemplary embodiment differs from third in that only three lines 321a, 321b, 321c of Hall switches 320a; 320b; 320c, considered in cross-section (FIG. 9), are arranged at the corners of an equilateral triangle. Accordingly, here too the Hall switches 320a, 320b, 320c are placed overall along an imaginary helix around the pipeline-pig tube 314, enabling, in a manner analogous to the third exemplary embodiment, a gap-free tracking of the pipeline pig 312.

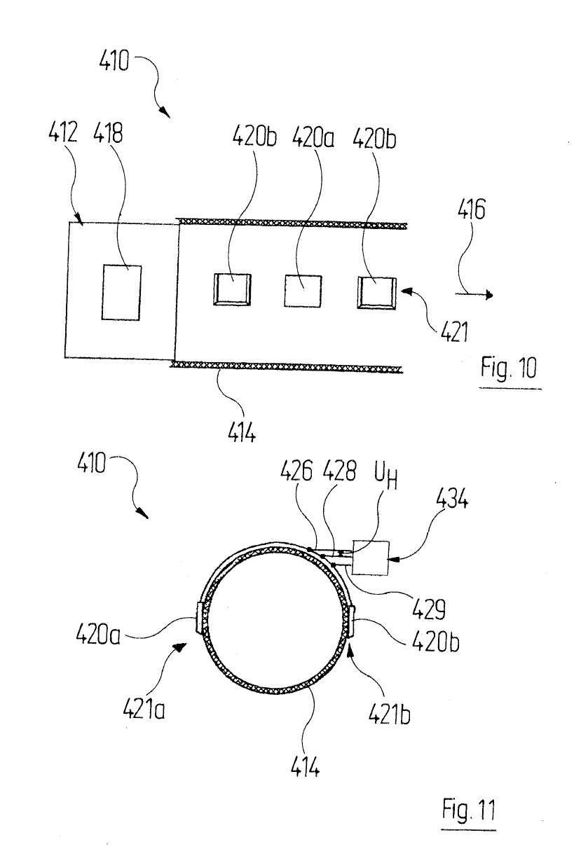

In a fifth exemplary embodiment, represented in FIGS. 10 (longitudinal section) and 11 (cross-section), those elements which are similar to those of the third exemplary embodiment, described in FIGS. 6 and 7, are provided with the same reference symbols plus 200, so that with respect to the description thereof reference is made to the remarks relating to the third exemplary embodiment. This exemplary embodiment differs from third in that only two lines 421a, 421b of Hall switches 420a, 420b, considered in cross-section (FIG. 11), are arranged on opposite peripheral sides of the pipeline-pig tube 414. Here too, the offset arrangement of the Hall switches 420a, 420b along an imaginary helix around the pipeline-pig tube 414 enables a gap-free tracking of the pipeline pig 412 in a manner analogous to the third exemplary embodiment.

In the exemplary embodiments of a device for pipeline-pig detection that have been described above, the following modifications, inter alia, are possible:

Instead of a single pipeline pig 12; 112; 212; 312; 412 use may also be made of a double-pipeline-pig system wherein the lacquer is conveyed between two pipeline pigs. In this case, at least one of the pipeline pigs is of the type of the pipeline pig 12; 112; 212; 312; 412 according to the invention.

Instead of the lacquer, a different coating material can also be conveyed in the pipeline-pig tube 14; 114; 214; 314; 414.

Instead of being wound directly around the pipeline-pig tube 14, in the first exemplary embodiment (FIGS. 1 to 4) the coil wire of the individual coils 20 may also have been wound around a coil-form, made of plastic for example. The coil-form with the coil winding can then be put onto the pipeline-pig tube 14. The coil-form may also be made of a different, also conductive, material instead of being made of plastic.

By way of coil, use may also be made of a so-called stoving-lacquer coil. In this case, it is a question of an air-cored coil, the windings of which are held together by cured (‘baked’) lacquer. Their inside diameter is somewhat larger than the outside diameter of the pipeline-pig tube 14, onto which they can therefore be easily pushed.

Instead of the ferrite core 18; 118; 218; 318; 418, a different magnetic-field source may also be provided. The pipeline pig 12; 112; 212; 312; 412 itself may also consist completely of a magnetic or magnetised material that is able to slide in the pipeline-pig tube 14; 114; 214; 314; 414 but nevertheless acts in sealing manner.

Instead of being equally spaced, in the first exemplary embodiment (FIGS. 1 to 4) the individual coils 20 may also bear against one another in a manner electrically insulated from one another, so that the pipeline-pig tube 14 is provided with individual coils 20 in gap-free manner.

Instead of being ascertained with the counter circuit 34h, 34i or with a counter card in the first exemplary embodiment, the number of a.c. voltage output pulses 36 can also be ascertained with a sine/cosine generator.

The components of the circuit arrangement 34; 134; 234; 334; 434 may be accommodated in a common housing or may be arranged separately.

Instead of the flexible pipeline-pig tube 14; 114; 214; 314; 414, use may also be made of a rigid pipeline-pig pipe.

In the second to fifth exemplary embodiments, instead of being integrated externally on the peripheral side the Hall switches 120; 220; 320; 420 may also be integrated, for example cast, into the wall of the pipeline-pig tube 112; 212; 312; 412.

It is again emphasized that the above-described embodiments of the present invention, particularly, any “preferred” embodiments, are possible examples of implementations merely set forth for a clear understanding of the principles of the invention. Many variations and modifications may be made to the above-described embodiments of the invention without substantially departing from the spirit and principles of the invention. All such modifications are intended to be included herein within the spirit of the invention and the scope of protection is only limited by the accompanying claims.

What is claimed is:

1. A device for non-contacting determination of a state variable, of at least one pipeline pig which is displaceable in a supply path and which includes a magnetic-field source, with
a) at least one sensor responding to the presence of the magnetic-field source; and,
b) a circuit arrangement, to which a sensor-output signal of the sensor can be supplied and which generates an electrical output signal that is representative of the state variables of the pipeline pig at the sensor,
wherein a plurality of sensors connected in parallel are arranged in succession along the supply path in the direction of motion of the pipeline pig.

2. The device of claim 1, wherein the sensors each include at least one conductor winding which is arranged around the supply path in the manner of a coil, the ends of which are connected to corresponding signal inputs of the circuit arrangement, whereby between the ends of the conductor winding an a.c. voltage sensor-output signal is applied which characterises the motion of the pipeline pig in the region of the conductor winding and which is induced with the magnetic-field source.

3. The device of claim 1, wherein the sensors each include a Hall element.

4. The device of claim 3, wherein the sensors are arranged around the supply path, in a uniformly distributed manner.

5. The device of claim 1, wherein the magnetic-field source of the pipeline pig is a permanent magnet or a ferrite core.

6. The device of claim 1, wherein the circuit arrangement exhibits means for determining electrical output signals from the sensor-output signal that are representative of at least one of the following state variables of the pipeline pig and/or of a coating material to be conveyed:
a) the position of the pipeline pig on the supply path,
b) the distance covered by the pipeline pig on the supply path,
c) the speed of the pipeline pig,
d) the volume of coating material conveyed with the pipeline pig, and,
e) the volumetric flow rate of the coating material conveyed with the pipeline pig

7. The device of claim 1, wherein the circuit arrangement exhibits means for transforming the a.c. voltage sensor-output signal into a square-wave signal.

8. The device of claim 1, wherein the circuit arrangement exhibits means for inverting the negative component or the positive component of the a.c. voltage sensor-output signal or of an a.c. voltage signal derived therefrom.

9. The device of claim 1, wherein the circuit arrangement exhibits means for counting sensor-output signals or signal pulses derived therefrom.

10. The device of claim 1, wherein the circuit arrangement exhibits a timing element.

11. The device of claim 1, wherein the circuit arrangement exhibits means for registering the sequence of negative and positive components of the a.c. voltage sensor-output signal.

12. A process for non-contacting determination of a state variable of at least one pipeline pig which is displaced in a supply path and by which a magnetic-field source is carried, wherein
a) the presence of the magnetic-field source is registered with at least one sensor;
b) a sensor-output signal of the sensor is supplied to a circuit arrangement, and with the latter an electrical output signal is generated that is representative of these state variables of the pipeline pig at the sensor,
wherein the presence of the magnetic-field source is registered with a plurality of sensors which are arranged in succession and connected in parallel along the supply path in the direction of motion of the pipeline pig.

13. The process of claim 12, wherein the respective conductor windings of the sensors, which are arranged around the supply path in the manner of a coil, an a.c. voltage sensor-output signal characterising the motion of the pipeline pig in the region of the conductor winding is induced with the magnetic-field source.

14. The process of claim 12, wherein a Hall voltage characterising the motion of the magnetic-field source or a digital output signal is generated with respective Hall elements.

15. The process of claim 14, wherein in the respective Hall elements are Hall switches.

16. The process of claim 12, where from the sensor-output signals electrical output signals are ascertained that are representative of at least one of the following state variables of the pipeline pig and/or of a coating material to be conveyed:
a) the position of the pipeline pig on the supply path,
b) the distance covered by the pipeline pig on the supply path,
c) the speed of the pipeline pig,
d) the volume of coating material conveyed with the pipeline pig, and,
e) the volumetric flow rate of the coating material conveyed with the pipeline pig.
